(19) United States
(12) Patent Application Publication
(10) Pub. No.: US 2023/0335431 A1
(43) Pub. Date: Oct. 19, 2023

(54) SEMICONDUCTOR DEVICE AND METHOD FOR MANUFACTURING THE SAME

(71) Applicant: Silergy Semiconductor Technology (Hangzhou) LTD, Hangzhou (CN)

(72) Inventor: Huan Wang, Hangzhou (CN)

(21) Appl. No.: 18/131,952

(22) Filed: Apr. 7, 2023

(30) Foreign Application Priority Data
Apr. 19, 2022 (CN) 202210409725.0

(51) Int. Cl. H01L 21/762; H01L 29/78; H01L 29/66

(52) U.S. Cl. CPC H01L 21/76224; H01L 29/7816; H01L 29/66681

(57) ABSTRACT

A method of making a semiconductor device can include: providing a semiconductor substrate; etching the substrate to form a trench therein; filling the trench with an insulating material, wherein a top surface of the insulating material is higher than a top surface of the trench; etching the insulating material to expose sharp corners at a junction of sidewalls of the trench and an upper surface of the substrate; forming a field oxide layer on a portion of the upper surface of the substrate and the insulating material, where the field oxide layer covers one of the sharp corners; and oxidizing correspondingly the sharp corner covered by the field oxide layer, at the junction of the trench sidewalls and the upper surface of the substrate, in order to form into a round corner.

### RELATED APPLICATIONS

This application claims the benefit of Chinese Patent Application No. 202210409725.0, filed on Apr. 19, 2022, which is incorporated herein by reference in its entirety.

### FIELD OF THE INVENTION

The present invention generally relates to the field of semiconductor technology, and more particularly to semiconductor devices and methods of manufacturing the semiconductor devices.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1 is a partial cross-sectional view of an example LDMOS transistor.

FIG. 2 is a structure diagram of an example LDMOS transistor, in accordance with embodiments of the present invention.

FIGS. 3A-3G are structural diagrams of steps of an example manufacturing method of the semiconductor device, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die are mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

The manufacturing process of semiconductor integrated circuits mainly can include the formation of devices such as transistors in the active region of the surface of the semiconductor substrate. These devices need to be isolated from each other through isolation structures. Both trench isolation structure and field oxide isolation structure are often used to isolate the active region of semiconductor substrate.

In making power devices (e.g., laterally-diffused metal-oxide-semiconductor [LDMOS] devices), and particularly using a local oxidation of silicon (LOCOS) process to form the field oxide layer, there are a number of different devices/designs on the junction between the high-voltage field oxide isolation structure and the shallow trench isolation structure (STI). Because of the particularity of the LOCOS process, it can be easy to form upward sharp corners at the junction. After the process has completed, the sharp corners at the junction can form charge accumulation, which may reduce the actual thickness of the field oxide layer between the substrate and the polysilicon layer. This can result in the breakdown of the field oxide layer at the junction and reliability issues with gate oxide integrity (GOI).

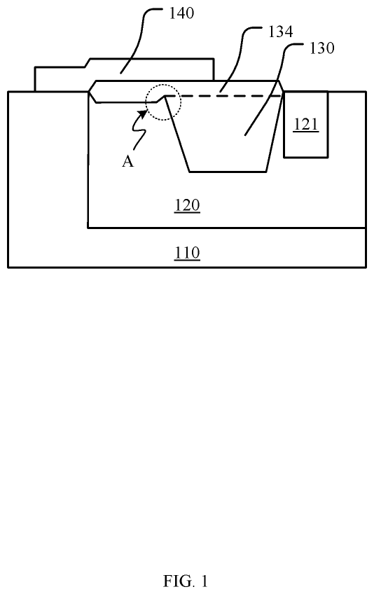

Referring now to FIG. 1, shown is a partial cross-sectional view of an example LDMOS transistor. In this example, a cross-sectional view of this portion of the LDMOS transistor is shown as a partial structure located within drift region 120 of substrate 110. Drift region 120 of the LDMOS transistor can include field oxide layer 134 and shallow trench isolation structure 130. On the surface of substrate 110, gate structure 140 may also be included, which is at least partially located on the surface of field oxide layer 134. In portion of the dotted circle A, it can be seen that a sharp corner is formed at the junction of the upper surface of substrate 110 and the trench sidewall. The sharp corner may form charge accumulation, and the thickness of the oxide layer between this portion of the charge and gate structure 140 can be reduced. This can result in breakdown of the oxide layer of sharp corner at the junction, and reduction of device reliability.

In an ideal situation, it can be expected that the sharp corners at the junction of the upper surface of substrate 110 and side walls of the trench 101 will be as small or absent as possible. However, during the process of forming field oxide layer 134 in the field oxide layer region by a LOCOS process, substrate 110 at the junction of the upper surface of substrate 110 and side walls of trench 101 may not be exposed. Therefore, sharp corners can inevitably occur, causing charge accumulation, and resulting in a decrease in the reliability of the device.

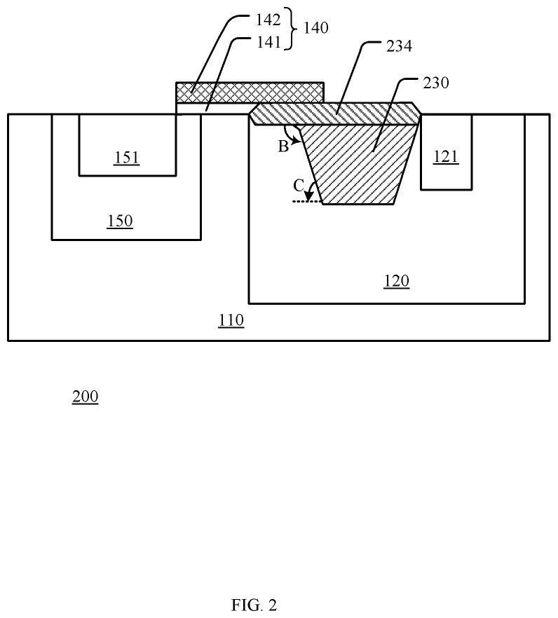

Referring now to FIG. 2, shown is a structure diagram of an example LDMOS transistor, in accordance with embodiments of the present invention. In this particular example LDMOS transistor 200, the sharp corners at the junction between the trench sidewalls of shallow trench isolation structure 230 and the surface of substrate 110 are substantially eliminated, thus improving device reliability. Here, LDMOS transistor 200 can include substrate 110, body region 150 and drift region 120 located in substrate 110, source region 151 located in body region 150, drain region 121 and shallow trench isolation structure 230 located in drift region 120, field oxide layer 234 located on the surface of shallow trench isolation structure 230, and gate structure 140 located on the surface of substrate 110.

For example, body region 150 and drift region 120 can be spaced apart by a predetermined distance. Also, at least a portion of gate structure 140 can be located on the surface of the substrate between source region 151 and shallow trench isolation structure 230. In addition, at least a portion of gate structure 140 can be located on the surface of field oxide layer 234. In this example, gate structure 140 can include gate oxide layer 141 and conductor layer 142.

In particular embodiments, shallow trench isolation structure 230 and drain region 121 can be located in drift region 120, and field oxide layer 234 may be located on the surface of the drift region 120 and the surface of shallow trench isolation structure 230. Drain region 121 can be adjacent to shallow trench isolation structure 230 and located in an area on a side of shallow trench isolation structure 230 away from source region 151. That is, the drain region and the source region may be located at opposite sides of the trench. In this example at the mark B, the junction between the trench sidewalls and the surface of substrate 110 may have an obtuse angle of an arc shape, which can avoid charge accumulation caused by small sharp corners, thereby improving the yield and reliability of the device.

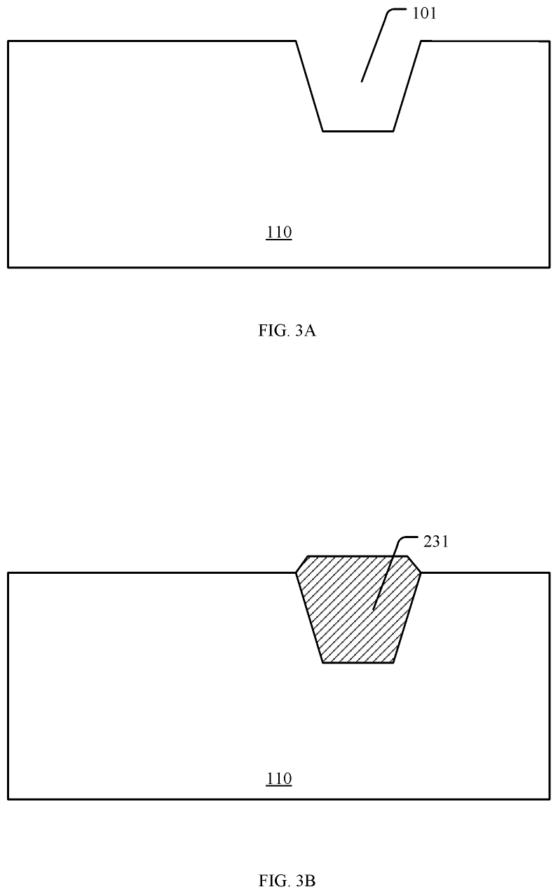

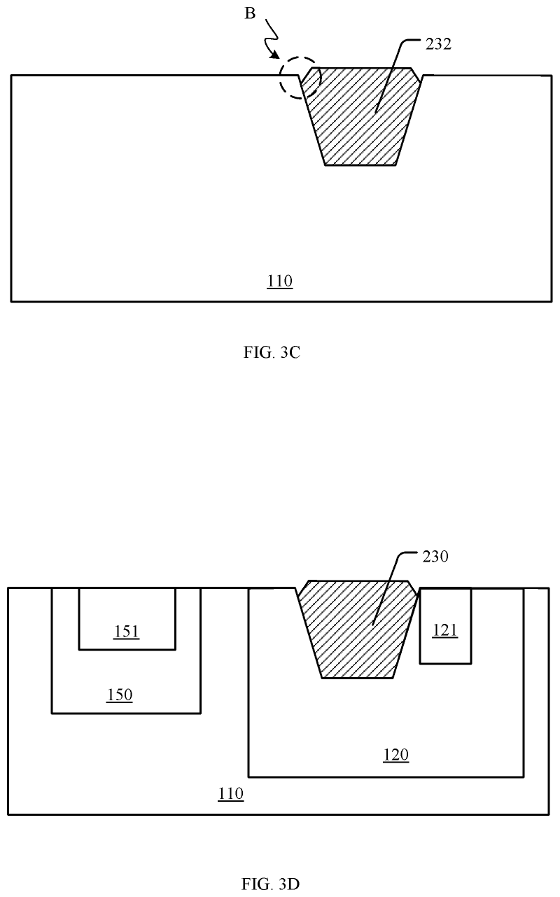

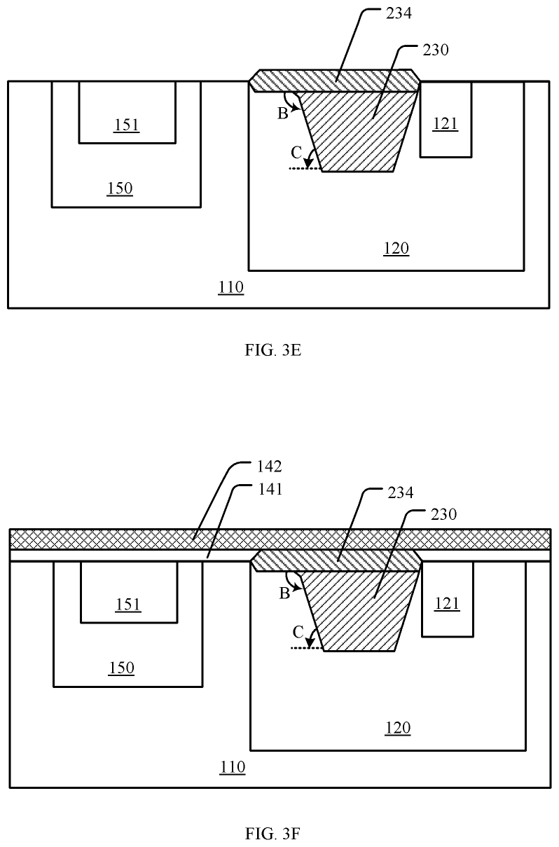

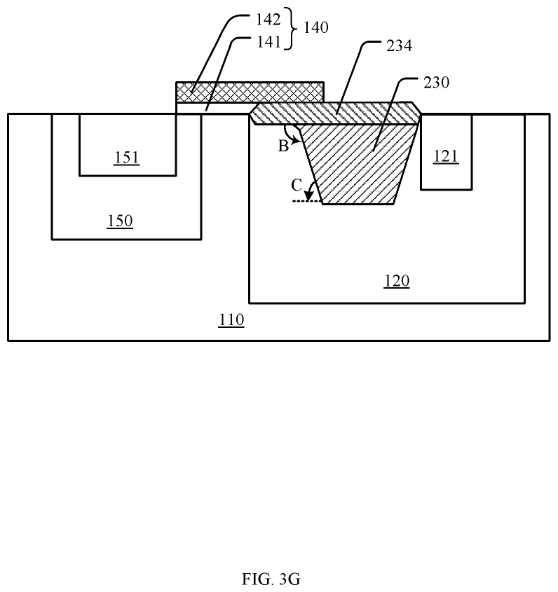

Referring now to FIGS. 3A-3G, shown are structural diagrams of steps of an example manufacturing method of the semiconductor device, in accordance with embodiments of the present invention. The method can begin by providing semiconductor substrate 110. The material of substrate 110 can be monocrystalline silicon (Si) or monocrystalline germanium (Ge), silicon germanium (GeSi), or silicon carbide (SiC), or other materials, such as gallium arsenide and other Group III-V compounds.

Trench 101 can be formed in substrate 110, and insulating material 231 may be deposited in trench 101, as shown in FIGS. 3A and 3B. For example, forming shallow trench isolation structure 230 can include forming a photoresist layer on the surface of semiconductor substrate 110. The pattern of shallow trench isolation structure 230 can be defined by photolithography. In other words, an opening can be formed in the portion of the photoresist layer corresponding to shallow trench isolation structure 230, in order to form a photoresist mask. Then, trench 101 can be formed in semiconductor substrate 110 by etching downward from the opening in the photoresist mask. By controlling the etching time, the opening in semiconductor substrate 110 reaches a desired depth to form trench 101. Side walls of trench 101 can be inclined outwards with an inclination angle of less than or equal to 90 degrees. In this example, trench 101 is an inverted trapezoid with an inclination angle of from about 65 degrees to about 70 degrees. The inclination angle may be too large to affect the depositing insulating material in the following steps. Then, insulating material 231 can be deposited in trench 101 to fill trench 101, whereby a top surface of the insulating material is higher than a top surface of the trench.

The etching of trench 101 described above can be performed by a dry etching process, such as ion milling etching, plasma etching, reactive ion etching, laser ablation, or by selective wet etching using an etchant solution. After the etching process, the photoresist mask can be removed by dissolving or ashing in a solvent. The deposition process of insulating material 231 described above is, e.g., one selected from electron beam evaporation (EBM), physical vapor deposition (PVD), chemical vapor deposition (CVD), atomic layer deposition (ALD), and sputtering. As an example, a reactive ion etching process can be utilized for etching, and a chemical vapor deposition process for depositing insulating materials (e.g., silicon dioxide).

Further, insulating material 231 can be etched back to obtain insulating material 232, as shown in FIG. 3C. Here, the deposited insulating material 231 can be etched back through wet etching to expose sharp corners at the junction between sidewalls of trench 101 and the upper surface of substrate 110, as shown by the dotted circle B in FIG. 3C.

In particular embodiments, the solution used for wet etching is, e.g., hydrofluoric acid. By controlling the time of wet etching, it is possible to control the degree of exposure of sharp corners at the junction of the upper surface of substrate 110 and the sidewalls of trench 101. In other examples, other solutions that eliminate oxides can also be used, such as solutions with high selectivity for oxides. One example is a buffered oxide etch (BOE), which can be formed by mixing hydrofluoric acid (49%) with water or ammonium fluoride with water, or hydrofluoric acid with different ratios (e.g., 1:10, 1:100, etc.). Further, the solution concentration of wet etching can be changed to change the wet etching rate, thereby changing the degree of exposure of sharp corners at the junction.

In particular embodiments, etched insulating material 232 may serve as a shallow trench isolation structure in the final device structure. Therefore, the shallow trench isolation structure is referred to as insulating material 232 below. Further, body region 150 and drift region 120 can be formed in substrate 110 through an ion implantation process, source region 151 may be formed in body region 150, and drain region 121 can be formed in drift region 120, as shown in FIG. 3D.

The forming of body region 150 and drift region 120 can include forming a photoresist layer on the surface of semiconductor substrate 110. Photolithography can be used to define a pattern of body region 150 and drift region 120 to form a photoresist mask, and then ion implantation may be performed on substrate 110 by the photoresist mask to form body region 150 and drift region 120. For example, the implanted ions in body region 150 are of a first doping type, and the implanted ions in drift region 120 are of a second doping type, whereby the first doping type is opposite to the second doping type. Therefore, two masks and two ion implantation may be required to form body region 150 and drift region 120.

In this example, body region 150 can be located at a distance from drift region 120, and the trench and shallow trench isolation structure 230 may be located in the drift region. The extension depth of drift region 120 in substrate 110 can be greater than that of body region 150 in substrate 110. This can be achieved by controlling the energy and ion implantation time during ion implantation processes. Further, the forming of source region 151 and drain region 121 can include forming a photoresist layer on semiconductor substrate 110. Photolithography can be used to define a pattern of the ion implantation region, that is, forming an opening in the portion of the photoresist layer corresponding to the ion implantation region to form a photoresist mask. Subsequently, using ion implantation and drive techniques, ion implantation can be performed to form a doped region, such as source region 151 and/or drain region 121, in the semiconductor substrate 110.

Through multiple mask processes and ion implantation processes, source region 151 can be formed in body region 150 of substrate 110, and drain region 121 may be formed in drift region 120. Drain region 121 can be located in drift region 120 on the side of shallow trench isolation structure 230 away from body region 150. Further, by controlling the parameters of ion implantation, such as implantation energy and dose, it is possible to achieve the desired depth and obtain the desired doping concentration. Using an additional photoresist mask can control the lateral extension of the doped region.

In this example, source region 151 and drain region 121 can also be formed using a dual diffusion process. In a double diffusion process, two implantations in the same region and a high-temperature propulsion process can be performed. For example, when the conductive type of the LDMOS transistor is N-type, in order to form source region 151, the dopant for the first ion implantation is, e.g., arsenic, and the doping concentration is relatively high, while the dopant for the second ion implantation is, e.g., boron, and the doping concentration is relatively low. During the high-temperature propulsion process after two ion implantation, because boron diffuses faster than arsenic, boron may defuse farther horizontally than arsenic, and the lateral extension distance of the low doped region may thus be greater than the lateral extension distance of the high doped region to form a lateral concentration gradient.

In this example, body region 150 and drain region 151 may have a first doping type, drift region 120 and source region 151 may have a second doping type, and the first doping type is opposite to the second doping type. For example, the first doping type is one of N-type and P-type, and the second doping type is the other of N-type and P-type. In order to form an N-type semiconductor layer or region, N-type dopants (e.g., P, As) can be injected into the semiconductor layer and region. In order to form a P-type semiconductor layer or region, a P-type dopant (e.g., B) can be doped in the semiconductor layer and region. Further, field oxide layer 234 can be formed on a surface of part of substrate 110 and a surface of shallow trench isolation structure 230, as shown in FIG. 3E.

In this step, field oxide layer 234 may be formed on a portion of the surface of substrate 110 and the surface of shallow trench isolation structure 230 by using the LOCOS process, as shown in FIG. 3E. For example, field oxide layer 234 can be configured as an oxide layer. Field oxide layer 234 may be located on the surface of substrate 110 of drift region 120 and extend laterally on the surface of the shallow trench isolation structure 230 to being adjacent to drain region 121. A thickness of field oxide layer 234 can be adjusted according to the withstand voltage level of the semiconductor device. As an example, the thickness of field oxide layer 234 can be between 300 Å and 1000 Å (e.g., 800 Å). Field oxide layer 234 may not be limited to a high-voltage field oxide layer, and in some cases may be applied to any thickness of oxide layers, such as field oxide layers or gate oxide layers.

For example, the LOCOS process for forming field oxide layer 234 can include forming a nitride protective layer on the surface of substrate 110, and forming an opening in the nitride protective layer to expose a portion of the surface of substrate 110 and the surface of shallow trench isolation structure 230. Thermal oxidation process can be performed, and an oxide layer may be grown on a portion of the surface of substrate 110 and the surface of shallow trench isolation structure 230 through a high-pressure field oxide furnace tube. In this way, field oxide layer 234 can be formed. Also, the surface of field oxide layer 234 may be higher than the surface of substrate 110.

In this example, after forming field oxide layer 234, the deposited insulating material can be seamlessly connected to field oxide layer 234 to form an integration to improve the quality of shallow trench isolation structure 230. In addition, due to the exposure of sharp corners at the junction between shallow trench isolation structure 230 and surface of substrate 110, during the thermal oxidation of the LOCOS process, due to the simultaneous oxidation of the upper surface and the side surfaces, the oxidation rate at the sharp corners may rapidly increase. Ultimately, the sharp corner can be eliminated to form a smooth junction, which can greatly eliminate sharp corner charges, increase the thickness of the oxide layer at the interface, and improve the breakdown voltage and reliability of device.

Further, gate oxide layer 141 and conductor layer 142 can be formed on the surface of substrate 110, as shown in FIG. 3F. Here, gate oxide layer 141 may be formed, e.g., through a furnace tube oxidation process. Then, conductor layer 142 can be formed on the surface of gate oxide layer 141, via a suitable deposition process as described above. For example, conductor layer 142 may be a metal layer, a doped polysilicon layer, or a laminated gate conductor including a metal layer and a doped polysilicon layer, or other conductive materials, such as TaC, TiN, TaSiN, HfSiN, TiSiN, TiCN, TaAlC, TiAlN, TaN, PtSix, Ni3Si, Pt, Ru, W, and a combination of the various conductive materials. In this particular example, conductor layer 142 is a polysilicon layer.

In addition, gate oxide layer 141 and conductor layer 142 can be etched to form gate structure 140, as shown in FIG. 3G. Here, a photoresist mask can be formed on the semiconductor structure. The photoresist mask may define the pattern of gate structure 140. In other words, an opening can be formed outside the portion of the photoresist layer corresponding to gate structure 140, the photoresist layer may only be located on the surface of gate structure 140, and the surface of conductor layer 142 in the other regions can be exposed. Then, etching downward from the opening in the photoresist mask may be performed in order to remove the exposed portion of conductor layer 142, thereby exposing the surface of gate oxide layer 141. Etching can continue downward from the opening in the photoresist mask, and the exposed portion of gate oxide layer 141 may also be etched, exposing the surface of substrate 110. After the etching process, the photoresist mask can be removed by dissolving or ashing in solvent.

In this example, gate oxide layer 141 can be located between conductor layer 142 and substrate 110, and gate oxide layer 141 may extend laterally on the surface of substrate 110 between source region 151 and drift region 120. One part of conductor layer 142 can be located on the surface of gate oxide layer 141, and the other part of conductor layer 142 may be located on the surface of field oxide layer 234. Further, at least a portion of gate oxide layer 141 and conductor layer 142 may be located on the surface of source region 151 in body region 150.

In particular embodiments, after forming gate structure 140, an interlayer insulating layer can be on the obtained semiconductor structure. Also, through holes can be formed to penetrate the interlayer insulating layer to reach the source region, drain region, and conductor layer. Wirings or electrodes can be located on the upper surface of the interlayer insulating layer and, thereby completing other portions of the LDMOS transistor.

In particular embodiments, after the shallow trench isolation structure is formed, the shallow trench isolation structure can be etched using a wet etching process to expose the sharp corners at the junction between the shallow trench isolation structure and the upper surface of the substrate. During the subsequent formation of the field oxide layer, the sharp corners at the junction may also be rapidly oxidized to form field oxide layer, thereby eliminating the sharp corners, improving the breakdown voltage, and improving the reliability of the LDMOS transistor.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method of making a semiconductor device, the method comprising:
a) providing a semiconductor substrate;
b) etching the substrate to form a trench therein;
c) filling the trench with an insulating material, wherein a top surface of the insulating material is higher than a top surface of the trench;
d) etching the insulating material to expose sharp corners at a junction of sidewalls of the trench and an upper surface of the substrate;
e) forming a field oxide layer on a portion of the upper surface of the substrate and the insulating material, wherein the field oxide layer covers one of the sharp corners; and
f) oxidizing correspondingly the sharp corner covered by the field oxide layer, at the junction of the trench sidewalls and the upper surface of the substrate, in order to form into a round corner.

2. The method of claim 1, wherein the forming the field oxide layer comprises using a local oxidation of silicon method.

3. The method of claim 1, wherein during the etching the insulating material to expose the sharp corners at the junction of the trench sidewalls and the upper surface of the substrate, the insulating material is back etched using wet etching process.

4. The method of claim 3, wherein a solution of the wet etching process comprises hydrofluoric acid, buffered oxide etching solution (BOE), or hydrofluoric acid with different ratios.

5. The method of claim 4, wherein a rate of the wet etching process is changed by changing the etching time or concentration of the solution for wet etching to control the exposure of the sharp corner at the junction of the trench sidewalls and the upper surface of the substrate.

6. The method of claim 1, wherein between the etching the insulating material and the forming the field oxide layer on the insulating material, further comprising:
a) forming a body region and a drift region in the semiconductor substrate using an ion implantation process;
b) forming a source region in the body region and a drain region in the drift region; and
c) wherein the trench is located in the drift region, and the drain region and the source region are located at opposite sides of the trench.

7. The method of claim 2, wherein the forming the field oxide layer by the oxidation process comprises using a high-pressure field oxide furnace tube, and a thickness of the field oxide layer is between 300 Å and 1000 Å.

8. The method of claim 1, wherein the thickness of the field oxide layer is 800 Å.

9. The method of claim 1, wherein the insulating material comprises silicon dioxide, and the field oxide layer comprises silicon dioxide.

10. The method of claim 1, wherein after the forming the field oxide layer on the insulating material, further comprising forming a gate structure on the surface of the field oxide layer and a portion surface of the substrate.

11. The method of claim 10, wherein the forming the gate structure on the surface of the field oxide layer and a portion surface of the substrate comprises:
a) depositing a gate oxide layer on the surface of the substrate;
b) depositing a conductive layer on the surface of the field oxide layer and the gate oxide layer;
c) etching the gate oxide layer and the conductor layer through a patterned mask; and
d) wherein the gate oxide layer extends on the substrate surface between the source region and the field oxide layer, and the conductor layer extends on the gate oxide layer and a portion of the field oxide layer.

12. A semiconductor device, comprising:
a) a semiconductor substrate having a trench therein;
b) an insulating material filled in the trench;
c) a field oxide layer formed on a portion of an upper surface of the substrate and the insulating material, wherein a junction between sidewalls of the trench and the upper surface of the substrate is rounded.

13. The semiconductor device of claim 12, further comprising:
a) a body region and a drift region located in the substrate;
b) a source region located in the body region;
c) a drain region located in the drift region; and
d) wherein the trench is located in the drift region, and the drain region and the source region are located at opposite sides of the trench.

14. The semiconductor device of claim 12, wherein a thickness of the field oxide layer is between 300 Å and 1000 Å.

15. The semiconductor device of claim 12, wherein the thickness of the field oxide layer is 800 Å.

16. The semiconductor device of claim 13, further comprising a gate structure having a gate oxide layer and a conductor layer, wherein the gate oxide layer extends on a substrate surface between the source region and the field oxide layer, and the conductor layer extends on the gate oxide layer and a portion of the field oxide layer.
